(19) United States
(12) Patent Application Publication
(10) Pub. No.: US 2025/0271266 A1
(43) Pub. Date: Aug. 28, 2025

(54) THREE-AXIS ROTATION RATE SENSOR WITH A SUBSTRATE AND A DOUBLE ROTOR

(71) Applicant: Robert Bosch GmbH, Stuttgart (DE)

(72) Inventors: Andreas Lassl, Korntal-Muenchingen (DE); Jochen Reinmuth, Reutlingen (DE); Matthias Kuehnel, Boeblingen (DE); Matthias Wenzel, Marbach Am Neckar (DE); Nils Felix Kuhlmann, Ehningen (DE)

(21) Appl. No.: 19/037,639

(22) Filed: Jan. 27, 2025

(30) Foreign Application Priority Data
Feb. 23, 2024 (DE) 10 2024 201 674.8

(51) Int. Cl. G01C 19/56

(52) U.S. Cl. CPC G01C 19/56

(57) ABSTRACT

A three-axis rotation rate sensor. The sensor includes a substrate and a double rotor including a first rotor and a second rotor elastically connected to each other via a first coupling element such that the two rotors are excitable to antiphase rotary oscillations, the first rotor including a first and a second seismic mass, which are deflectably mounted vis-à-vis the first rotor and the second rotor includes a third and a fourth seismic mass, which are deflectably mounted vis-à-vis the second rotor, the first mass being connected to the third mass via a first rocker element such that the third mass is deflected in an opposite lateral direction upon a lateral deflection of the first mass, the second mass being connected to the fourth mass via a second rocker element such that the fourth mass is deflected in an opposite lateral direction upon lateral deflection of the second mass.

### CROSS REFERENCE

The present application claims the benefit under 35 U.S.C. § 119 of German Patent Application No. DE 10 2024 201 674.8 filed on Feb. 23, 2024, which is expressly incorporated herein by reference in its entirety.

### FIELD

The present invention relates to a three-axis rotation rate sensor.

### BACKGROUND INFORMATION

Rotation rate sensor assemblies are described in the related art in numerous embodiments. In a simple variant, for example, a rotor is arranged in a MEMS functional plane (XY plane) parallel to a substrate and is excited to oscillation. If an external rotation rate in the X or Y direction is applied to the MEMS component, the rotor is deflected by the Coriolis force in the Z direction. This deflection can in turn be determined via a change in capacitance compared to fixed detection electrodes. It is advantageous to use two detection electrodes which are arranged symmetrically to the axis of rotation; the differential signal of these is used as the rotation rate signal. In this arrangement, an external linear acceleration produces an equal capacitance change for both detection electrodes, whereby the differential signal remains unchanged. It is thus not possible for an externally applied acceleration to interfere with the rotation rate signal.

Furthermore, some conventional arrangements with two symmetric rotors are excited to antiphase oscillation and are equipped with four symmetric detection electrodes in each direction of detection. Capacitances are coupled in a cross-wise manner and the resulting differential signal is measured. If an external rotary oscillation is applied to a single rotor, which rotary oscillation has the frequency of the drive oscillation, then this rotary oscillation will produce a deflection of the rotor that cannot be distinguished from a rotational rate signal. In a system with two rotors oscillating in phase opposition, in contrast, in the event of an externally applied rotary oscillation, the signal of the first rotor is precisely compensated for by the signal of the second rotor oscillating in phase opposition. A further advantage of this arrangement is that no torque is coupled out of the MEMS system with the antiphase oscillation of the two rotors. Therefore, regardless of the mounting conditions, no rotational energy can be transferred from the system to the surrounding environment. Furthermore, it is advantageous to spring-mount the rotors at their center.

The suspension of the movable structures and the coupling between the Coriolis masses oscillating in phase opposition always form a critical point in the design of rotation rate sensors. External interferences such as vibrations, electrical measurement pulses, or the electronic noise of the evaluation circuit may lead to the excitation of undesirable oscillatory modes, which may lead to a false signal or an additional noise component in the signal depending on the mode of oscillation. Experience has shown that the simpler and more compact the sensor's design is, the less susceptible it is to interference. Therefore, a rotation rate sensor which only comprises two centrally suspended rotors and possibly also a coupling structure can also be a very robust and resistant system.

A disadvantage of such an arrangement is that only a rotational rate in the X and Y directions can be measured, while a measurement in the Z direction is not possible. An arrangement for three-axis measurement by means of a single rotor with additional seismic masses for the Z direction is described in this respect, in European Patent Application No. EP 1 832 841 A1. There are various approaches to realize a detection of the Z direction based on the double rotor arrangement as well, but these always require additional elements that are coupled to the movement of the two rotors. Due to the additional elements and their coupling structures, the three-axis rotation rate sensors are usually very complex, have very many, in particular very soft spring elements and are thus very susceptible to interference from external vibrations or electrical measurement pulses.

### SUMMARY

It is an object of the present invention to provide an arrangement of a three-axis rotation rate sensor that is vibrationally robust, that preferably does not couple any energy out, that is unsusceptible to electrical measuring pulses, that can be realized in a small area, and that has a high level of sensitivity and good utilization of space.

A rotation rate sensor having certain features of the present invention makes it possible to detect external rotation rates with respect to all three spatial directions, wherein the drive movement in this case consists of the rotary oscillations of the rotors. Without an external rotation rate, the two rotors are initially arranged parallel to the XY plane. If the sensor has an external rotation applied to it with an axis of rotation directed parallel to the XY plane, Coriolis forces act on the rotors such that the rotors tilt with respect to the plane. With an external rotation rate, the axis of rotation of which is perpendicular to the main extension plane, in contrast, only radial extension or compression forces act that cannot cause an overall movement of the rotor. However, the rotors of the sensor according to the present invention themselves in turn comprise deflectable seismic masses that are rotated along with the rotary oscillation of the rotors, so that the radial Coriolis forces cause displacement of the seismic masses in the radial direction of the rotor, which can be detected correspondingly. Both the drive oscillations of the two rotors and the detection movements of the seismic masses run in phase opposition, respectively, due to the first and second coupling elements according to the present invention, so that the deflection of the seismic masses can be precisely determined via a differential measurement.

The rotors thus perform a dual function in the sensor according to the present invention and function as a mass of detection both in the X and Y directions and in the Z direction, so that a particularly compact sensor can be realized in this way without additional elements being necessary for this purpose. Advantageously, a double rotor can be designed with very good use of space and can be adapted well to different external conditions. The concept according to the present invention requires very few mass and coupling elements compared to other three-axis sensors, so that the sensor has much fewer interference modes at higher frequencies and is less prone to external interference. In addition, the sensor according to the present invention requires fewer springs as a whole and can in particular be realized with harder springs than conventional concepts. The sensor is thus much less susceptible to variation in the manufacturing process, which is the reason why particularly soft springs can be produced only very inaccurately. In this way, it is advantageously possible to produce rotation rate sensors that have a narrower frequency distribution than conventional sensors.

According to an example embodiment of the present invention, the geometric description of the electromechanical structure of the sensor is hereinafter based on the main extension plane of the substrate. The directions parallel to the substrate are referred to as lateral directions and the direction perpendicular to the substrate is referred to as the vertical direction. The lateral directions are here spanned by an X direction and a Y direction standing perpendicular on the X direction. The X and Y directions together with the vertical Z direction form a perpendicular coordinate system, wherein the relative location of individual components with respect to the Z direction are also referred to by the terms “above” and “below” and vertical movements are referred to as “upward” and “downward.”

For example, the two rotors of the double rotor may be spaced apart in the X direction and are coupled such that they can be excited via the drive, in particular an electrostatic drive, to rotary oscillations in phase opposition relative to the substrate. The axes of rotation of both rotors run in the Z direction, wherein two rotation directions can be distinguished, one of which is designated as rotating to the right (i.e., clockwise with respect to a top view of the substrate) and the other as rotating to the left (counter-clockwise). The axis of rotation preferably passes through the center, more preferably through the center of gravity, of the respective rotor. The antiphase oscillations of the double rotor are movements in which the first and the second rotor rotate respectively in the opposite direction at any point in time. Stated another way, the first rotor reaches the maximum deflection with respect to clockwise rotation when the second rotor reaches the maximum deflection with respect to counterclockwise rotation, and vice versa. In the following, rotations of the entire sensor are always referred to as external or externally applied rotations or rotation rates in order to distinguish them from rotations of the rotors. Each of the two rotors, in turn, has two seismic masses elastically coupled to the respective rotor so as to enable lateral deflection relative to the rotor. The lateral deflection direction of the first mass is parallel to the lateral deflection direction of the second mass and the deflection direction of the third mass is accordingly parallel to that of the fourth mass. When the two rotors are respectively in their un-deflected resting positions with respect to the rotation, the lateral deflection directions of all four seismic masses are in particular parallel to each other, for example in the Y direction.

The seismic masses may in particular be partitioned segments of the rotors separated from the rest of the respective rotor by one or multiple clearances and connected to it by springs. For example, the rotors may have a rectangular or square shape with respect to their lateral extent, while the seismic masses may be rectangular, square, or trapezoidal, for example. In order to make possible the lateral deflections, the springs are designed in particular to be soft in the deflection direction, i.e., they have a lower spring constant or stiffness in this direction than in the directions perpendicular to it. Preferably, the spring constant in the lateral deflection direction is at most half of what it is in the lateral direction perpendicular to it and/or in the vertical direction. Preferably, leaf springs with a high aspect ratio in the Z direction are used for this purpose, wherein the height (extension in the Z direction) is at least twice the width (extension in the lateral direction) of the spring. If the lateral deflection is in the Y direction, for example, an advantageously high sensitivity is achieved in the X direction, wherein the sensitivity remains nearly unchanged compared to a pure double rotor without Z detection. According to the present invention, the seismic masses are coupled via the rocker elements such that the lateral deflections of the first and third masses and the second and fourth masses run respectively in phase opposition. In particular, in this movement, the rocker elements tilt parallel to the substrate, such that, for example, one end of the first rocker element follows the lateral deflection of the first mass, while the opposite end follows the lateral deflection of the third mass. According to the present invention, these antiphase movements are, in turn, coupled via the second coupling element such that the lateral deflections of the seismic masses have the following phase relationships: the movements of seismic masses belonging to the same rotor (first and second masses and third and fourth masses, respectively) are antiphase, and the movements of seismic masses connected by a rocker element (first and third and second and fourth masses, respectively) are also antiphase.

The sensor according to an example embodiment of the present invention is preferably suspended only at four points on the substrate, which are arranged relatively centrally and symmetrically to one another. This causes the sensor to react significantly less sensitively to bending such as, for example, that caused by mechanical stresses during further processing. Each of the two rotors preferably has a single anchor point, wherein the anchor points of both rotors may lie, for example, on a line parallel to the X direction. Each of the two rocker elements preferably also has a single anchor point, which is particularly preferably arranged centrally with respect to a main direction of extension of the rocker element, so that each rocker element is divided in the longitudinal direction into two partial sections, which form equally long lever arms with respect to the anchor point. For example, the anchor points of the two rocker elements may be on a line parallel to the Y direction and spaced apart in the Y direction. The first coupling element is preferably designed to not only couple the drive oscillation of the two rotors, but also to couple the tilting movements of the two rotors caused by an external rotational rate in the X direction. Preferably, the first coupling element extends in the X direction between the two rotors and is elastic with respect to extension or compression with respect to this direction. In particular, for this purpose, the first coupling element may comprise two or more partial sections running in the Y direction that bend in the X direction upon extension or compression of the first coupling element and thus induce the desired elasticity. If an outer rotation rate in the X direction is now applied, each rotor rotates about an axis in the Y direction due to the tilt caused by the Coriolis forces, wherein the tilts of the two rotors are antiphase due to the opposite rotation directions. The first coupling element, in particular, generates a return force directed so that the two rotors are retracted into the non-tilted position parallel to the substrate, so that the antiphase oscillations of the tilts are supported correspondingly by the coupling. Further, the two rocker elements can preferably be configured to couple the vertical movements of the seismic masses particularly well, wherein the main direction of extension of the rocker elements can run in particular parallel to the X direction. The first rocker element preferably couples the vertical movement (relative to the substrate) of the first and third seismic mass such that the third mass is deflected in a direction opposite the vertical deflection of the first mass, and vice versa, when the first mass is deflected vertically. Stated differently, an upward movement of the first mass is associated with a downward movement of the second mass (and vice versa). With these movements of the first and third masses, the rocker element tilts in particular from its idle position which runs parallel to the substrate, so that a first end of the rocker element connected to the first mass moves upwards as the opposite end connected to the third mass moves downwards (and vice versa). The second and fourth seismic masses are coupled via the second rocker element in an analogous manner. The respective mass elements coupled in pairs are in turn coupled to each other via the second coupling element. It is possible here that a return force is realized between antiphase tilts of the rocker elements by the second coupling element, for example in the form of a torsion spring.

In the system according to an example embodiment of the present invention, all the detection masses are thus coupled to each other in all detection directions by the first and second coupling elements and the two rocker elements. The coupling of all individual detection masses causes them each to oscillate at the exact same frequency. Thus, unlike uncoupled systems, unwanted beats in the detection movement can be avoided. This further results in the possibility of shifting the frequencies of the detection movements via additional electrodes so that they have the same value as the frequency of the drive movement. This improves the quality of detection, which makes particularly sensitive sensors possible. Furthermore, sensors that operate with a particularly favorable closed-loop concept can also be realized in this way.

Advantageous embodiments and developments of the present invention can be found in the disclosure herein.

According to an example embodiment of the present invention, preferably, the two rotors are connected to the substrate at their center, in particular at their center of gravity, via at least one spring.

According to an example embodiment of the present invention, particularly preferably, the axis of rotation of the rotors also passes through the center or the center of gravity. A rotor may be attached to the substrate, for example, via an anchor point at which one, two or more springs connected to the rotor are arranged parallel to the substrate. The at least one spring can in particular be configured as a hard spring, so that it can be produced with lesser process variation compared to softer springs (i.e., in particular, springs having a smaller width).

The arrangement and geometrical shape of the double rotor, the seismic masses and the coupling elements may advantageously be designed symmetrically so that the forces and torques caused by the detection elements moved in phase opposition to one another are exactly compensated for. In this way, a transfer of kinetic energy to the substrate and an offset in the measurement signal generated by the corresponding detection movement may be advantageously prevented. The following information on symmetry always relates to the lateral arrangement, shape and extent of the individual elements, i.e., the symmetry relationships are described as two-dimensional symmetries with respect to the main extension plane. In the three-dimensional arrangement, the respective axes of symmetry indicated correspond to planes of symmetry that are spanned by the axis of symmetry and the Z direction. Preferably, the entire sensor structure is to be designed symmetrically, so that interference of any type is already compensated for solely by the symmetry. According to a preferred embodiment, it is provided that the double rotor is designed symmetrically to a first and/or a second axis of symmetry, wherein the first axis of symmetry is in the Y direction and is arranged centrally between the two rotors, and the second axis of symmetry is in the X direction and runs through a center, in particular a center of gravity, of the first rotor and a center, in particular a center of gravity, of the second rotor. In particular, the two rotors are spaced apart in the X direction and are configured to mirror each other with respect to the first axis of symmetry extending between them.

In particular, according to an example embodiment of the present invention, each of the two rotors can independently be designed in mirror symmetry with respect to the second axis of symmetry extending through its center. Preferably, the first and second masses and, respectively, the third and fourth masses are mirror images with respect to the second axis of symmetry. Particularly preferably, the spring assemblies, via which the seismic masses are connected to the respective rotor, are correspondingly designed symmetrically.

According to one example embodiment of the present invention, the first rotor is designed axisymmetric to a third axis of symmetry and/or the second rotor is designed axisymmetric to a fourth axis of symmetry, wherein the third axis of symmetry in the Y direction passes through a center, in particular a center of gravity, of the first rotor and the fourth axis of symmetry in the Y direction passes through a center, in particular a center of gravity, of the second rotor. Preferably, both rotors are each configured to be mirror-symmetrical with respect to their central axis extending in the Y direction.

Preferably, according to an example embodiment of the present invention, the seismic masses arranged on the rotors are also configured to be mirror symmetrical with respect to the third and/or fourth axis of symmetry, i.e., each of the masses is preferably symmetrical with respect to the axis of symmetry of the respective rotor extending in the Y direction. Particularly preferably, the spring assemblies of the seismic masses also have the corresponding symmetry.

Preferably, according to an example embodiment of the present invention, the first coupling element is a first spring element arranged centrally between the rotors, wherein the first spring element is in particular formed by at least one leaf spring, which is preferably oriented predominantly in the Y direction. Particularly preferably, the first spring element comprises one or multiple partial sections which run in the Y direction and bend in the X direction correspondingly when the spring element is loaded in the X direction. For example, the first spring element may comprise one or multiple U-shaped or O-shaped sections, which spread in the X direction when loaded. Alternatively, a meandering-shape sequence of partial sections is also possible. Preferably, the first spring element is at least twice as stiff with respect to deflection in the Z direction than in the Y direction. Preferably, a leaf spring with a high aspect ratio in the Z direction is used, e.g., with a height that is at least twice the width of the spring.

According to a preferred embodiment of the present invention, it is provided that the rocker elements each comprise a lever element, connected to a seismic mass of the first rotor via a second spring element and connected to a seismic mass of the second rotor via a third spring element, wherein the second and third spring elements are preferably each arranged centrally on a seismic mass and/or the lever element is anchored to the substrate via a fourth spring element, wherein the fourth spring element is, particularly preferably, arranged centrally on the lever element and/or extends from the lever element towards a center of the double rotor. Preferably, the connection of the spring elements to the respective seismic mass is arranged in the center (with respect to the X direction) of the mass. Preferably, a leaf spring with a high aspect ratio is used for this purpose, in particular a leaf spring with a height at least twice the width of the spring. The lever element is anchored to the substrate via at least a fourth spring element, wherein the fourth spring element and the anchoring are aligned with the center of the double rotor to make a compact design possible. It is advantageous to design each of the two rocker elements in a mirror-symmetrical manner with respect to the first axis of symmetry, as well as to use two identical rocker elements that are designed as the mirror images of one another with respect to the second axis of symmetry. In this way, in turn, energy outcoupling and an offset in the measurement signal are avoided.

According to a preferred embodiment of the present invention, the second coupling element comprises a first and second additional arm and a bending element, wherein the first additional arm is arranged on the first rocker element and the second additional arm is arranged on the second rocker element, wherein the bending element connects the first additional arm to the second additional arm. The additional arms are preferably attached to the lever element of the respective rocker element symmetrically and centrally between the two rotors in order to avoid an offset. The bending element connecting the two additional arms is preferably designed as a leaf spring, wherein a leaf spring with a high aspect ratio can be used for this purpose, in particular a leaf spring at least twice as tall as it is wide. The length of the leaf spring is preferably selected to be less than the length of the additional arms, i.e., less than the Y section of the additional arms between the lever element and the bending element, so that a parallel deflection of the seismic masses is suppressed particularly well.

Preferably, according to an example embodiment of the present invention, the second coupling element is arranged at least in a sub-area above or below the first coupling element or comprises at least two parallel sub-elements in a sub-area, wherein one sub-element is arranged above the first coupling element and the other sub-element is arranged below the first coupling element. Stated another way, the first coupling element, which runs in particular in the X direction, and the second coupling element, which runs in particular in the Y direction, cross in an area between the rotors and the second coupling element is routed in the crossing area in a plane below or above (or below and above) the first coupling element.

In particular, it is favorable to realize the connection between the additional arms and the bending element via a mechanical bridge that bridges a portion of the first coupling element. For example, the bending element may be connected to a bridge element in a second functional layer vertically spaced apart from the functional layer of the rotors. If only a thin second functional layer can be produced in the manufacturing process, it is advantageous to prevent the buckling between the two lever arms by an additional spring element that is soft in the X direction, but stiff in the Z direction and that is connected to the substrate on one side and to the lever element on the other side. The bridge element may be disposed below or above the first coupling element or may branch into two parallel sub-elements, one arranged above and the other below the first coupling element. The bridge element is then routed in a sub-area below or above the first coupling element and is connected to a lever arm, respectively. Favorably, a bridge element is connected both below and above the first coupling element so that buckling between the two lever arms in the area of the bridge element under load can be avoided.

According to an example embodiment of the present invention, preferably, a first detection electrode assembly disposed below and/or above the first rotor is designed symmetrically to the second and/or third axis of symmetry and/or a second detection electrode assembly disposed below and/or above the second rotor is designed symmetrically to the second and/or fourth axis of symmetry. The first detection electrode arrangement, in particular, detects a tilting of the first rotor, such as that caused by an external rotation with an axis of rotation in the X or Y direction. Preferably, the first and second detection electrode assemblies each have at least four electrode surfaces, wherein the four electrodes of the first rotor are arranged in a mirror symmetrical manner with respect to the second and third axis of symmetry, respectively, while the four electrodes of the second rotor are mirror symmetrical with respect to the second and fourth axis of symmetry. Both the arrangement and the lateral form of the individual electrode surfaces (for example trapezoidal) obey the principle of double mirror symmetry. A tilt, whose axis of rotation is in the X direction, can in this way be realized by a differential measurement between the two electrode surfaces opposite one another in the Y direction. Analogously, a tilt perpendicular to this can be determined by the other respective pair of electrodes. Advantageously, asymmetric forces caused by electrical pulses on the electrodes are avoided by a symmetric electrode arrangement. For example, the detection electrodes for X and Y detection may be provided below (or above or below and above) the rotors.

According to an example embodiment of the present invention, it is particularly favorable if the X detection electrodes can also be provided below the seismic masses so that these areas are not lost but rather can be used twice.

According to a preferred embodiment of the present invention, it is provided that a third detection electrode assembly is configured to detect lateral deflection of the first and second seismic masses and a fourth detection electrode assembly is configured to detect lateral deflection of the third and fourth seismic masses, wherein the third and fourth detection electrode assemblies have an electrode surface disposed perpendicular to the substrate. A rotation rate in the Z direction can be detected in a particularly favorable manner via perpendicularly arranged detection surfaces, which are provided in particular on the lever elements or are coupled to the lever elements. In this way, it is advantageously achieved that the lever elements are moved along during the detection movement, however they do not follow the drive movement and thus a rotation rate signal with a particularly low level of interference can be achieved. As in the X and Y directions, it is favorable to provide at least four electrode surfaces and to arrange them and connect them in pairs such that a rotary oscillation applied externally is compensated for exactly in the differential signal, so that no interference signal results.

According to a preferred embodiment of the present invention, the third and fourth detection electrode assemblies are configured to detect rotational movements of the rocker elements, the rotation axes of which run perpendicular to the main extension plane. In case of an external rotation with rotation axis that runs parallel to the Z direction, the seismic masses are deflected in the lateral direction and the rocker elements follow this movement by a rotational movement about the Z direction (i.e., by tilting parallel to the substrate). In particular, one end of the first rocker element follows the lateral deflection of the first mass, for example, while the opposite end follows the lateral deflection of the third mass. The rotation of the rocker elements can be used to determine the associated deflection of the seismic masses. The rotational movement of the rocker elements can in particular be detected in that the third and fourth detection electrode arrangement each comprise electrodes that are fixedly connected to the substrate and further electrodes that are fixedly connected to the rocker elements. The rotation of the rocker elements relative to the substrate can in this way be determined capacitively via the relative displacement of the associated electrodes.

According to an example embodiment of the present invention, in a symmetrical construction with the arrangements of the detection electrodes described above, the sensor is not sensitive in any direction with respect to external acceleration or rotational acceleration. An exception arises when acceleration is in the X direction, which can cause the lever elements to deflect, corresponding to an apparent Z rotation rate.

According to an example embodiment of the present invention, it is advantageous to select the mass distribution of the lever elements, including the additional arms and the bending element, as well as the suspension of the lever elements, such that in case of an acceleration in the X direction, the lever elements are compensated for such that they do not execute a rotational movement but only a displacement in the X direction.

Embodiment examples of the present invention are shown in the figures and explained in more detail in the following description.

### BRIEF DESCRIPTION OF THE DRAWINGS

FIG. 1 schematically shows an example embodiment of the rotation rate sensor according to the present invention.

FIG. 2 schematically shows an example embodiment of the rotation rate sensor according to the present invention, including the bending element between the two second coupling elements.

FIGS. 3A-3D schematically show the drive movement of the embodiment of the rotation rate sensor according to an example embodiment of the present invention.

FIG. 4 schematically shows the detection movement for an external rotation rate oriented in the Y direction.

FIG. 5 schematically shows the detection movement for an external rotation rate oriented in the X direction.

FIGS. 6A-6D schematically show the detection movement for an external rotation rate oriented in the Z direction, according to an example embodiment of the present invention.

FIG. 7 schematically shows a further embodiment of the rotation rate sensor according to the present invention.

FIGS. 8A=8C illustrate a preferred design of the rocker structure, according to an example embodiment of the present invention.

### DETAILED DESCRIPTION OF EXAMPLE EMBODIMENTS

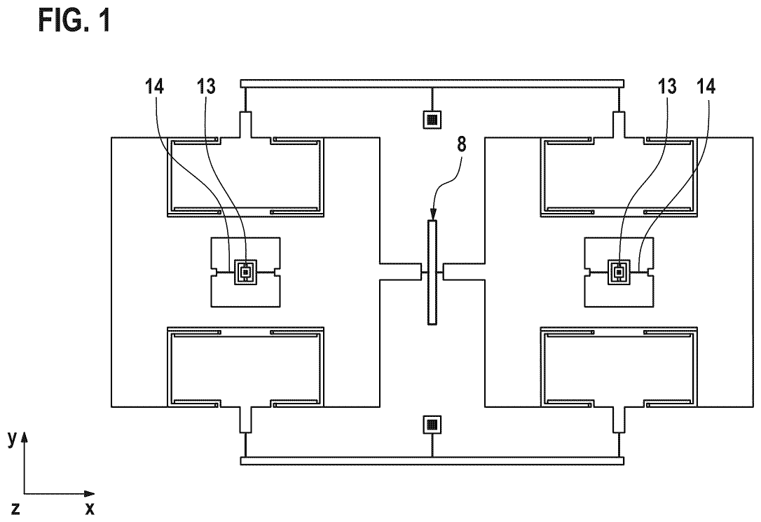

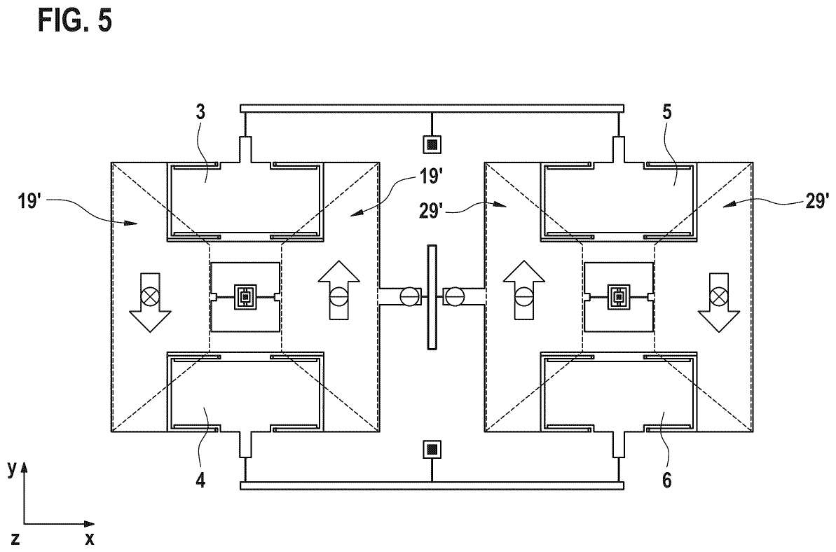

In FIG. 1, the sensor assembly according to the present invention is shown schematically. The basic element is formed by a double rotor oscillating in phase opposition. In the two rotors 1, 2, two seismic masses 3, 4, 5, 6 are respectively divided, which are mounted using soft springs 7 in a direction perpendicular to the axis of oscillation of the rotors. The two rotors are coupled to each other via a first coupling element 8, which in the embodiment shown comprises a centrally arranged O-shaped section, which is spread in the X direction when loaded. Each one of the two divided masses (3 with 5 and 4 with 7) of a rotor 1, 2 are coupled to one other via a rocker element 9 and 9′, respectively. The rocker elements 9, 9′ force an antiphase lateral deflection of the masses 4 and 6, and 3 and 5, respectively (cf. FIG. 5).

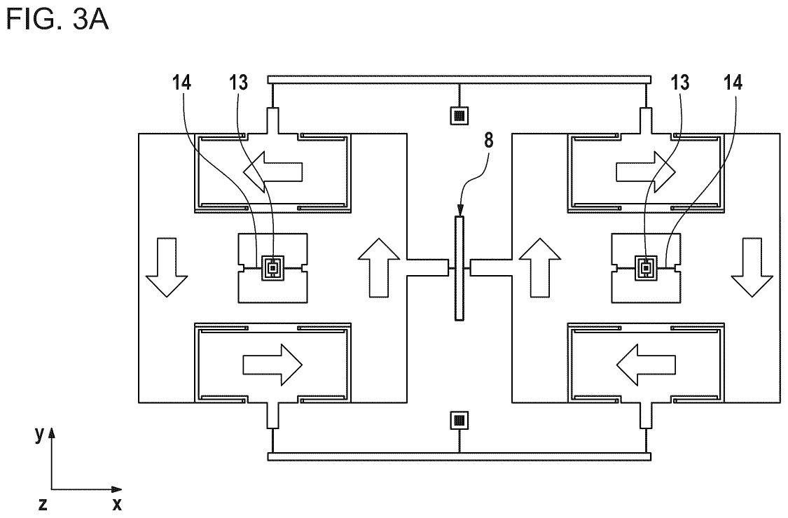

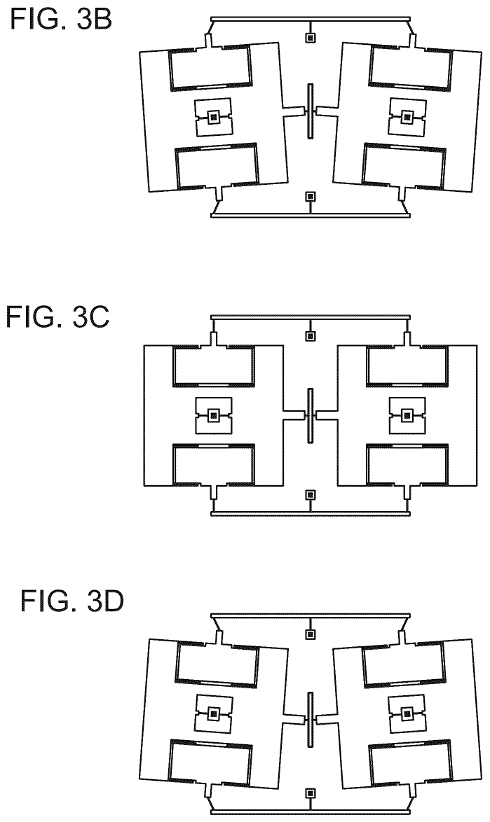

The illustrated arrangement has multiple axial symmetries, through which a transfer of kinetic energy to the substrate and an offset in the measurement signal generated by the corresponding detection movement can advantageously be prevented. The two rotors 1, 2, their seismic masses 3, 4, 5, 6, the rocker elements 9, 9′ and the coupling elements 8, 10 are respectively designed in a mirror-symmetrical manner to the central axes of the double rotor extending in the X and Y directions. The axis of the left-right mirror symmetry of the arrangement shown is referred to as the first axis of symmetry, while the second axis of symmetry is associated with the mirror symmetry between the lower and upper half. In addition, each rotor 1, 2 has a mirror axis oriented in the Y direction, which is referred to as the third or fourth axis of symmetry, respectively. Preferably, the springs 7 of the seismic masses 3, 4, 5, 6 and the anchoring elements 13, 14 of the rotors 1, 2 (cf. FIG. 3) have the same symmetry as the rotors.

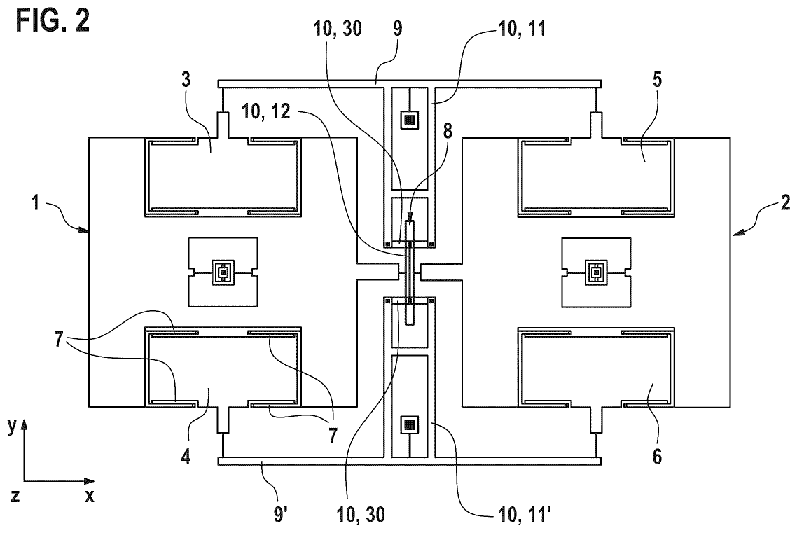

FIG. 2 shows a design of the sensor assembly according to the present invention as in FIG. 1, wherein the two rocker elements 9, 9′ are additionally connected via a second coupling element 10, which consists of two additional arms 11, 11′, which in turn are connected to each other via a bending element 12. In the illustrated, particularly favorable arrangement, the coupling structure 8 of the two rotors 1, 2 and the coupling structure 10 of the two rocker elements 9, 9′ are arranged between the two rotors, wherein a mechanical bridge 30 is realized in the central area in which the two coupling elements 8 and 10 cross that allows independent movement of both structures in this area. For this purpose, the coupling element comprises two sub-sections 30 (bridge elements) that run below the O-shaped section of the first coupling element 8.

FIGS. 3A-3D show the drive movement of the double rotor. In order to show the movement in a clearly visible manner, the second coupling element 10, which does not participate in this movement, is not depicted. As indicated by the arrows in FIG. 3A, the rotors 1, 2 are set into antiphase rotary oscillations by a drive (not shown). At the time shown in FIG. 3A, both rotors 1, 2 are in their zero position (cf. the idle state of the double rotor in FIG. 3C), and the left rotor 1 completes a counterclockwise rotation, while the right rotor 2 completes a clockwise rotation. FIG. 3B schematically shows the associated maximum deflection, while FIG. 3D shows the maximum deflection of the opposite oscillation phase (clockwise rotation of the rotor 1, counterclockwise rotation of the rotor 2). To make possible the rotary oscillation of the rotors 1, 2, the rotors 1, 2 each have a central clearance in the area of their center of gravity, in which they are connected to an anchor point 13 via spring elements 14.

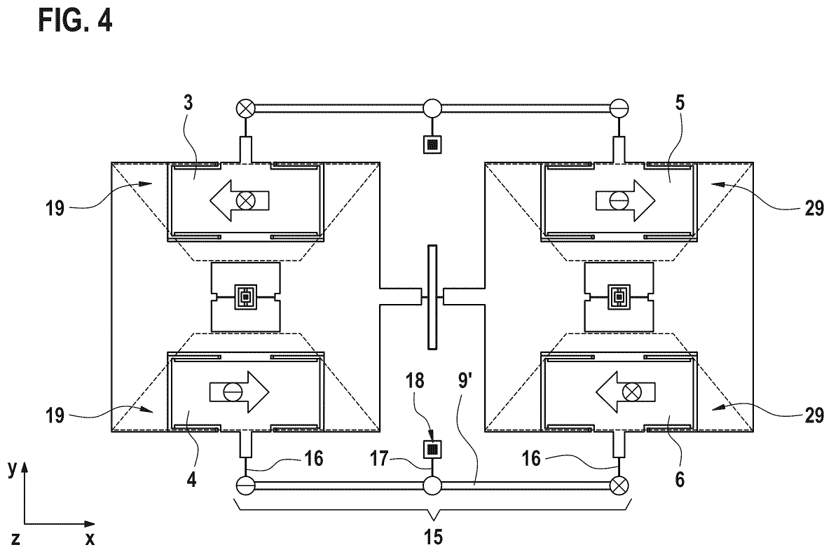

FIG. 4 schematically shows the movement of the seismic masses 3, 4, 5, 6, with which an external rotation is detected that runs parallel to the Y axis. In order to show the movement in a clearly visible manner, the second coupling element 10, which does not participate in this movement, is not depicted. Due to the antiphase rotary oscillation of the rotors 1, 2, the masses 3, 4, 5, 5, 6 move in the positive or negative X direction respectively during the illustrated passage through the zero position. Because of the Coriolis forces acting due to the external rotation, the two masses 3 and 6 are respectively deflected in the negative Z direction (i.e., downward) during their drive movement in the negative X direction. The masses 4 and 5 moved in phase opposition are correspondingly deflected in the positive Z direction (upward). The detection movements of the masses 3, 4, 5, 6 are coupled via the two rocker elements 9, 9′, each consisting of a lever element 15, which is connected via two springs 16 (second and third spring element) to the masses 4, 6 and 3, 5, respectively, and is connected to the anchor point 18 via a spring 17 (fourth spring element). Through the tilting movement of the levers 15 connected to the seismic masses 3, 4, 5, 6, the detection movements of the masses 3, 4, 5, 6 are coupled such that 3 and 5 and 4 and 6 are respectively deflected in phase opposition in the Z direction. The Z deflection is measured by the detection electrode assemblies 19 and 29 disposed above and/or below the double rotor, respectively, wherein the difference of the change in capacitance of the pair of electrodes 19 and 29, respectively, is included in the measurement signal. It is particularly advantageous to provide the X detection electrodes 19, 29 below the divided masses 3, 4, 5, 6 so that these areas are not lost but rather can be used twice.

FIG. 5 schematically shows the movement of the seismic masses 3, 4, 5, 6 with which an external rotation is detected that runs parallel to the X axis. In order to show the movement very clearly, the first coupling element 8, which does not participate in this movement, is not depicted. The detection movement is coupled via the two rocker elements 9, 9′. Due to the Coriolis forces, the right side of the rotor 1 (moving in the positive Y direction) is tilted upwards while the left side (moving in the negative Y direction) is tilted downwards. The second rotor 2 is tilted in a mirror image to this. The first coupling element 8 is advantageously designed to not only couple the drive oscillation of the two rotors 1, 2, but also couple the tilting movements of the two rotors 1, 2. Through the O-shaped section of the coupling element 8, it forms an elastic connection between the rotors 1, 2, through which the rotors 1, 2 are retracted into the non-tilted position. Detection is carried out analogously to FIG. 4 via the detection electrode assemblies 19′ and 29′.

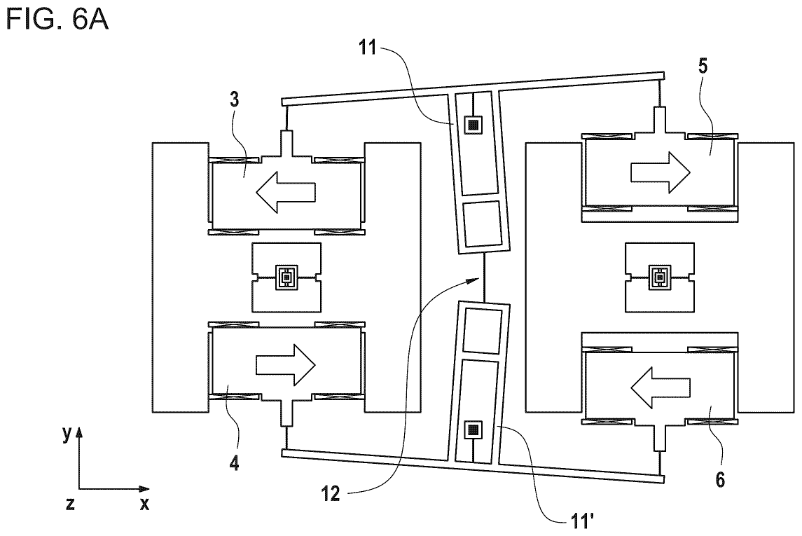

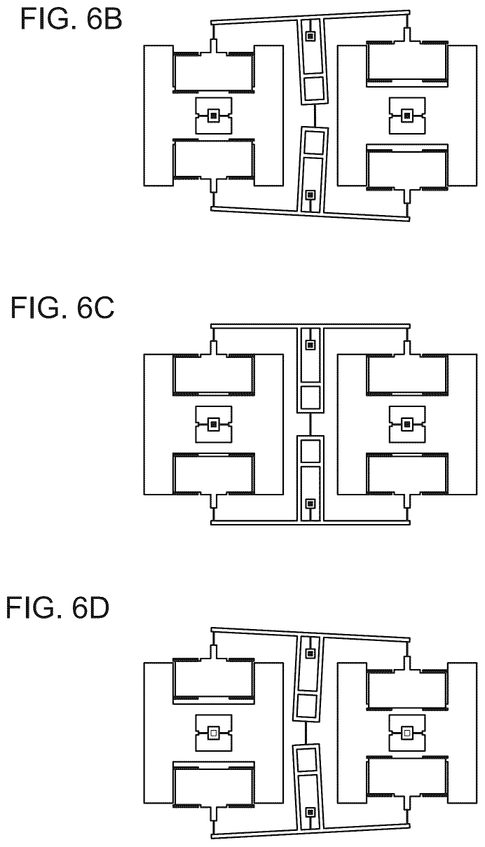

FIGS. 6A-6D schematically show the movement of the seismic masses 3, 4, 5, 6 with which an external rotation is detected that runs parallel to the Z axis. As shown in FIG. 6A, the masses 3, 4 of the first (counterclockwise rotating) rotor 1 are shifted by the Coriolis forces towards the center of the rotor 1, while the masses 5, 6 of the second rotor 2 are shifted away from the center of the rotor 2. These antiphase movements of the masses 3, 4, 5, 6 are supported by the second coupling element 10, on the one hand, in that it couples the lateral detection movements of the masses 3 and 5 and the lateral detection movements of the masses 4 and 6 together, and on the other hand by the spring element 12 arranged between the additional arms 11, 11′ that couples these pair-wise movements together. FIGS. 6A and 6B show the lateral deflections of the seismic masses when the left rotor 1 completes a counterclockwise rotation and the right rotor 2 completes a clockwise rotation. In FIG. 6D, the left rotor 1 completes a clockwise rotation and the right rotor 2 completes a counterclockwise rotation, and FIG. 6C shows the idle state of the double rotor for comparison.

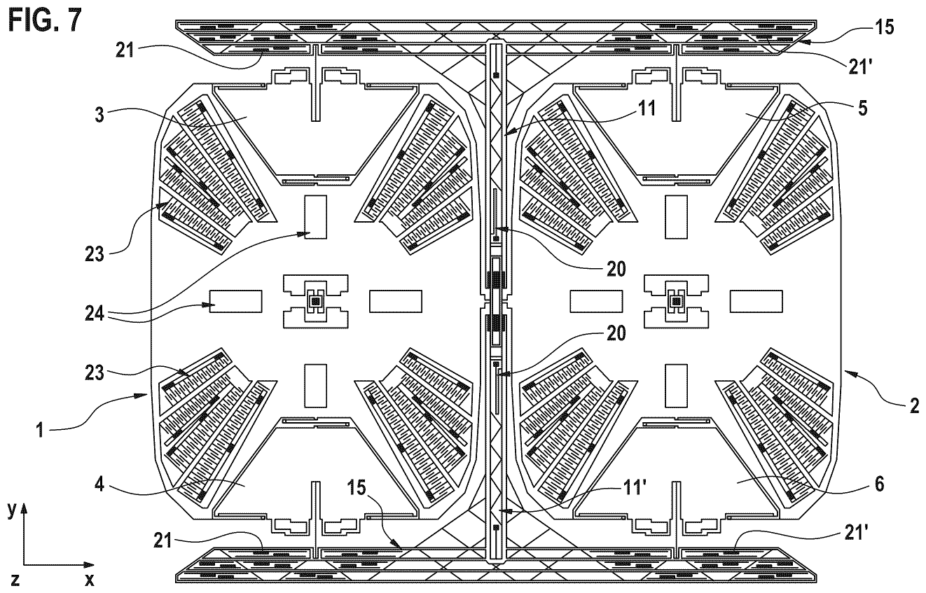

FIG. 7 shows a particularly advantageous implementation of the sensor concept according to the present invention. The high utilization of the area resulting from the large area share of the rotors 1, 2 can be seen. The drive electrodes 23 are realized in the form of comb electrodes fixedly connected to the rotors 1, 2, which are electrostatically coupled to comb electrodes fixed on the substrate. This full integration of the drive combs 23 into the rotors 1, 2 is advantageous in this design, especially with regard to the very large rotors. In this embodiment, areas 24 are also provided for quadrature compensation in all three spatial directions, although these are not actively operable in this design.

If only a thin second functional layer can be produced in the manufacturing process, it is advantageously preferable to prevent the buckling between the two lever arms 11, 11′ with an additional spring element 20, which is designed to be soft in the X direction but stiff in the Z direction and which is connected to the substrate on one side and to the respective lever arm 15 on the other side.

The Z rotation rate is detected here via vertically arranged detection surfaces 21, 21′, which are arranged on the lever arms 15 or can alternatively also be coupled with the lever arms. This is particularly advantageous because the lever arms 15 follow the detection movement but do not perform the drive movement, so that a rotation rate signal with a particularly low level of interference can be achieved. It is further advantageous to provide at least four detection surfaces 21, 21′ in the X and Y direction and to arrange and connect these in pairs such that an externally applied rotary oscillation is exactly compensated for in the differential signal so that no interference signal results.

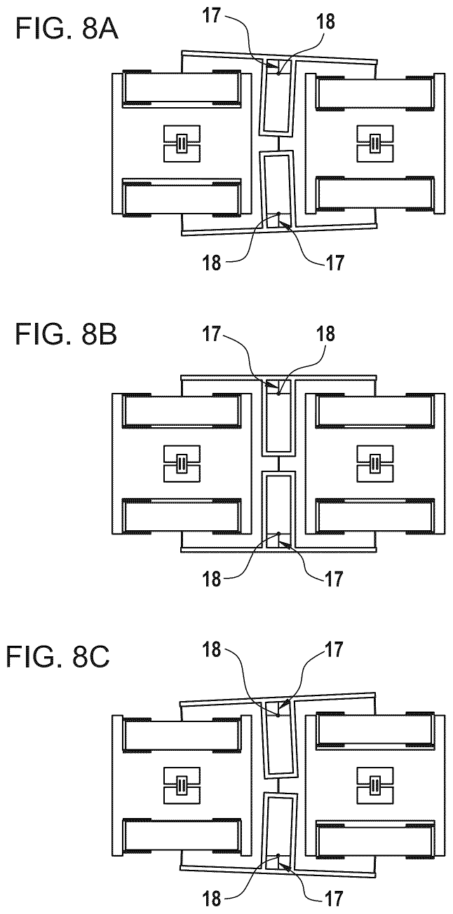

FIGS. 8A-8C illustrate the correct design of the suspension of the lever element 15. The lever elements 15 are each anchored to the substrate via a spring element 17 connected to an anchor point 18. FIGS. 8A, 8B and 8C show how the rocker structure can be symmetrized with respect to an acceleration applied in the X direction, so that an external acceleration cannot cause a false signal in the Z rotation rate signal. Symmetrization is achieved by choosing a suitable length for the spring 17 and by the corresponding positioning of the anchor point 18. FIG. 8A shows an undercompensated arrangement, FIG. 8B shows the correctly compensated arrangement, and FIG. 8C shows an overcompensated arrangement.

In a symmetrical construction with the arrangements of the detection electrodes described above, the sensor is not sensitive in any direction with respect to external acceleration or rotational acceleration. An exception is an acceleration in the X direction, which may cause the deflection of the lever arms 15 corresponding to an apparent Z-rotation rate (see FIGS. 8A and 8C). It is advantageous to select the mass distribution of the lever elements 15 including the additional arms 11, 11′ and the bending element 12 as well as the suspension 18 of the lever elements 15 such that, in the case of an acceleration in the X direction, the lever elements 15 are balanced such that they do not carry out any rotational movement, but rather only a displacement in the X direction (see FIG. 8B).

What is claimed is:

1. A three-axis rotation rate sensor, comprising:
a substrate and a double rotor, wherein the substrate has a main extension plane having an X and a Y direction, wherein the double rotor includes a first rotor and a second rotor, each elastically connected to the substrate via a suspension and each elastically connected to one another via a first coupling element, such that the first and second rotors are excitable to antiphase rotary oscillations, wherein axes of rotation of the first and second rotors run in a vertical Z direction perpendicular to the substrate, wherein the first rotor includes a first seismic mass and a second seismic mass, which are deflectably mounted with respect to the first rotor, wherein a lateral deflection direction of the first and second seismic masses of the first rotor runs parallel to the substrate, wherein the second rotor includes a third seismic mass and a fourth seismic mass, which are deflectably mounted with respect to the second rotor, wherein a lateral deflection direction of the third and fourth seismic masses of the second rotor runs parallel to the substrate, wherein the first seismic mass is connected to the third seismic mass via a first rocker element, such that, when the first seismic mass s deflected laterally, the third seismic mass is deflected into a direction opposite to the lateral deflection of the first seismic mass, wherein the second seismic mass is connected to the fourth seismic mass via a second rocker element, such that the fourth seismic mass s deflected in a direction opposite to the lateral deflection of the second seismic mass when the second seismic mass is deflected laterally.

2. The rotation rate sensor according to claim 1, wherein the first and second rocker elements are elastically connected to one another via a second coupling element, such that the lateral deflections of the first and second seismic mass are in phase opposition and the lateral deflections of the third and fourth seismic mass are in phase opposition.

3. The rotation rate sensor according to claim 1, wherein the two first and second rotors are connected to the substrate in their center of gravity via at least one spring.

4. The rotation rate sensor according to claim 1, wherein the double rotor is axially symmetric to a first and/or a second axis of symmetry, wherein the first axis of symmetry runs in the Y direction and is arranged centrally between the first and second rotors and the second axis of symmetry runs in the X direction through a center of gravity of the first rotor and a center of gravity of the second rotor.

5. The rotation rate sensor according to claim 1, wherein the first rotor is axially symmetric to a third axis of symmetry and/or the second rotor is axially symmetric to a fourth axis of symmetry, wherein the third axis of symmetry in the Y direction is runs through a center of gravity of the first rotor, and the fourth axis of symmetry in the Y direction runs through a center of gravity of the second rotor.

6. The rotation rate sensor according to claim 1, wherein the first coupling element is a first spring element centrally disposed between the first and second rotors, wherein the first spring element is formed by at least one leaf spring, which is oriented predominantly in the Y direction.

7. The rotation rate sensor according to claim 1, wherein the first and second rocker elements each include a lever element which is connected via a second spring element to a seismic mass of the first and second seismic masses of the first rotor and which is connected via a third spring element to a seismic mass of the third and fourth seismic masses of the second rotor, wherein the second and third spring elements are each centrally disposed on a seismic mass and/or the lever element is anchored to the substrate via a fourth spring element, wherein the fourth spring element is disposed centrally on the lever element and/or extends from the lever element towards a center of the double rotor.

8. The rotation rate sensor according to claim 1, wherein the second coupling element includes a first and second additional arm and a bending element, wherein the first additional arm is disposed on the first rocker element and the second additional arm is disposed on the second rocker element, wherein the bending element connects the first additional arm to the second additional arm.

9. The rotation rate sensor according to claim 1, wherein: (i) the second coupling element is disposed at least in a sub-area above or below the first coupling element, or (ii) includes two parallel sub-elements at least in one sub-area, wherein one sub-element of the sub-elements is disposed above the first coupling element, and the other sub-element of the sub-elements is disposed below the first coupling element.

10. The rotation rate sensor according to claim 1, wherein: (i) a first detection electrode assembly disposed below and/or above the first rotor is symmetrical to the second and/or third axis of symmetry, and/or (ii) a second detection electrode assembly disposed below and/or above the second rotor is symmetrical to the second and/or fourth axis of symmetry.

11. The rotation rate sensor according to claim 1, wherein a third detection electrode assembly is configured to detect the lateral deflection of the first and second seismic masses and a fourth detection electrode assembly is configured to detect the lateral deflection of the third and fourth seismic mass, wherein the third and fourth detection electrode assemblies include an electrode surface, arranged perpendicular to the substrate.

12. The rotation rate sensor according to claim 11, wherein the third and fourth detection electrode assemblies are configured to detect rotational movements of the first and second rocker elements, the rotational axes of which are perpendicular to the main extension plane.
